(19) United States
(12) Patent Application Publication
(10) Pub. No.: US 2009/0154112 A1
(43) Pub. Date: Jun. 18, 2009

(54) PACKAGING STRUCTURE OF POWER MODULE

(75) Inventors: Heng-Chia Fan, Taoyuan Hsien (TW); Zi-Ying Zhou, Taoyuan Hsien (TW)

Correspondence Address: KIRTON AND MCCONKIE, 60 EAST SOUTH TEMPLE,, SUITE 1800, SALT LAKE CITY, UT, 84111, US

(73) Assignee: DELTA ELECTRONICS, INC., Taoyuan Hsien (TW)

(21) Appl. No.: 12/135,102

(22) Filed: Jun. 6, 2008

(30) Foreign Application Priority Data
Dec. 14, 2007 (TW) 096147816

(51) Int. Cl. H05K 7/20

(52) U.S. Cl. 361/719; 361/707

(57) ABSTRACT

A power module includes a substrate, a power converter and a plurality of bond pads. The substrate includes a top surface and a bottom surface. The power converter is disposed on the substrate and includes at lease one semiconductor chip package. The semiconductor chip package is disposed on the top surface of the substrate. The bond pads are disposed on the bottom surface of the substrate, wherein at least some of the bond pads are electrically connected to the power converter and the plurality of bond pads have substantially identical area.

### FIELD OF THE INVENTION

The present invention relates to a packaging structure, and more particularly to a packaging structure of a power module with overall size reduction.

### BACKGROUND OF THE INVENTION

With the increasing development of power electronic, the internal circuitries of an electronic device are improved toward modulization. In other words, multiple electronic components are mounted on a substrate such as a printed circuit board and thus many functions are integrated into a single circuit module.

An example of the power module includes a power converter module such as a DC-to-DC converter module, an AC-to-DC converter module, and the like. By means of the power adapters, the input voltage may be converted into an output voltage required for the electronic devices.

Referring to FIG. 1, a schematic perspective view of a conventional power module 1 is illustrated. And several electronic components 11 of the power module 1 are used for converting the input voltage into the required voltage. The electronic components 11 include for example capacitors, resistors and control integrated circuits mounted on a side of the printed circuit board 10. Connectors 12 such as conductive pins are mounted on the other side of the printed circuit board 10 by a surface mount technology (SMT) in order to electrically interconnect the electronic components 11 on the printed circuit board 10 with a motherboard (not shown) of the electronic device. In addition, the heat generated from the electronic components 11 will be conducted to the motherboard through the conductive pins 12 for enhancing heat dissipation. As a consequence, the electronic device can operate normally.

Although the conventional power module 1 can achieve the purpose of power conversion, there are still some drawbacks. Since each of the conductive pins 12 has an inherent thickness, the overall thickness of the power module 1 is increased. In a case that the power module 1 is mounted on the motherboard, a great amount of space is occupied, which is detrimental to size reduction. Since it is difficult to control the thickness of the solder paste, the lower surfaces of the conductive pins 12 are usually not coplanar after the upper surfaces of these conductive pins 12 are bonded on the printed circuit board 10. In addition, the lengths of the relatively longer and shorter conductive pins 12 fail to be adjusted to be at the same levels. Under this circumstance, some conductive pins 12 fail to be in close contact with the solder paste coated on the motherboard and thus are often suffered from poor solderability. Therefore, the electrical connection and the structural stability between the printed circuit board 10 and the motherboard are impaired, and the product yield is reduced.

There is a need of providing a packaging structure of a power module to obviate the drawbacks encountered from the prior art.

### SUMMARY OF THE INVENTION

It is an object of the present invention to provide a power module to achieve overall package size reduction and high power density.

Another object of the present invention provides a power module to be mounted on a motherboard via bond pads according a surface mount technology (SMT), thereby increasing solderability and product yield.

In accordance with an aspect of the present invention, there is provided a power module. The power module includes a substrate, a power converter and a plurality of bond pads. The substrate includes a top surface and a bottom surface. The power converter is disposed on the substrate and includes at lease one semiconductor chip package. The semiconductor chip package is disposed on the top surface of the substrate. The bond pads are disposed on the bottom surface of the substrate, wherein at least some of the bond pads are electrically connected to the power converter and the plurality of bond pads have substantially identical area.

In an embodiment, at least some of the bond pads are arranged on a peripheral region of the bottom surface of the substrate.

In an embodiment, at least some of the bond pads are uniformly distributed over the peripheral region of the bottom surface of the substrate.

In an embodiment, at least some of the bond pads are contacted with the semiconductor chip package of the power converter such that the heat generated from the semiconductor chip package are conducted to the bond pads.

In an embodiment, a plurality of pure thermal pads are formed on the substrate corresponding to the semiconductor chip package such that the heat generated from the semiconductor chip package are conducted to the thermal pads.

In an embodiment, the pure thermal pads are formed on the substrate perpendicularly corresponding to the semiconductor chip package.

In an embodiment, a plurality of thermal vias formed in the substrate corresponding to the semiconductor chip package such that the heat generated from the semiconductor chip package are conducted to the thermal vias.

In an embodiment, the semiconductor chip package is a power chip package.

In an embodiment, the power converter further includes a plurality of passive components, which are electrically connected to the semiconductor chip package.

In an embodiment, the substrate is a printed circuit board.

In an embodiment, the power module is encapsulated with encapsulant.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view of a conventional power module;

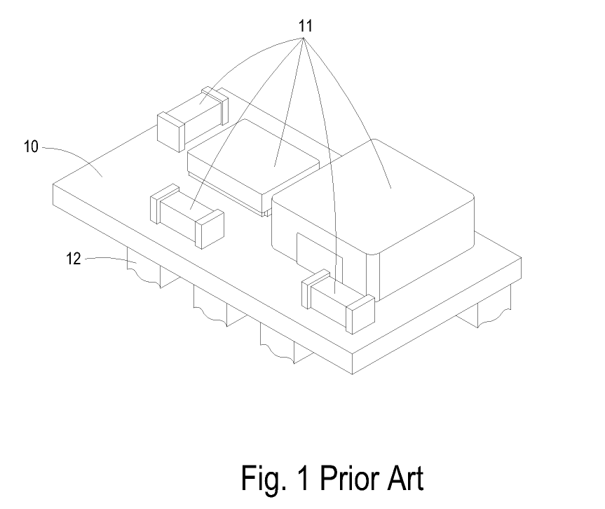

FIG. 2A is a schematic view of a package structure of a power module according to a first preferred embodiment of the present invention;

FIG. 2B is a schematic top view of the package structure of the power module shown in FIG. 2A for illustrating the electronic components disposed on the top surface of the substrate;

FIG. 2C is a schematic bottom view of the package structure of the power module shown in FIG. 2A for illustrating the layout configuration of multiple bond pads;

FIG. 3 is a schematic cross-sectional view illustrating arrangement of the semiconductor chip package, the substrate and the bond pad; and

FIG. 4 is a schematic circuit diagram illustrating the power converter of the power module according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

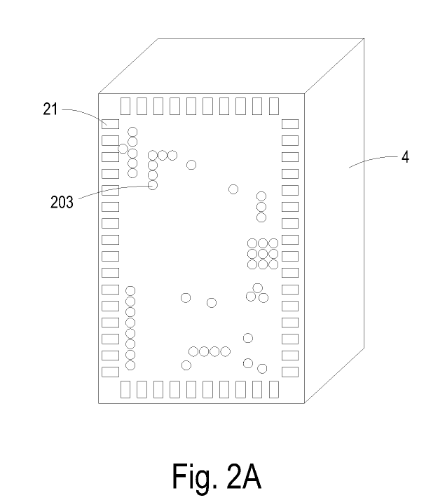

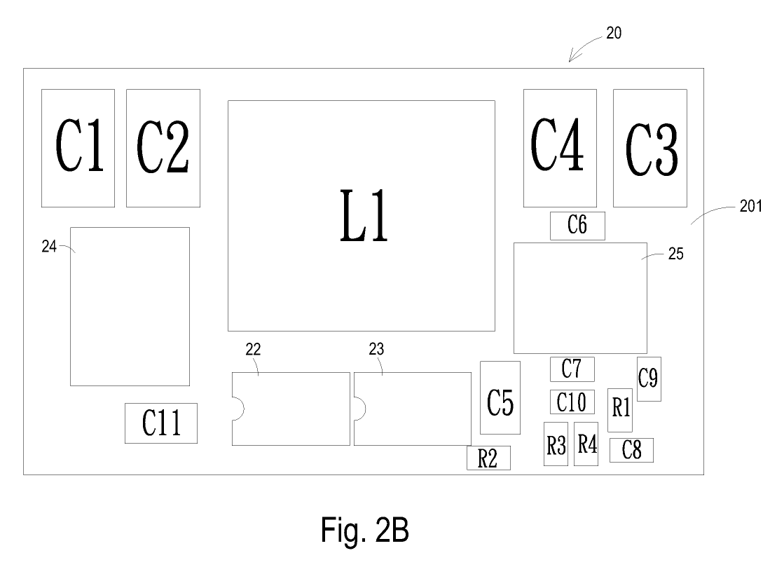

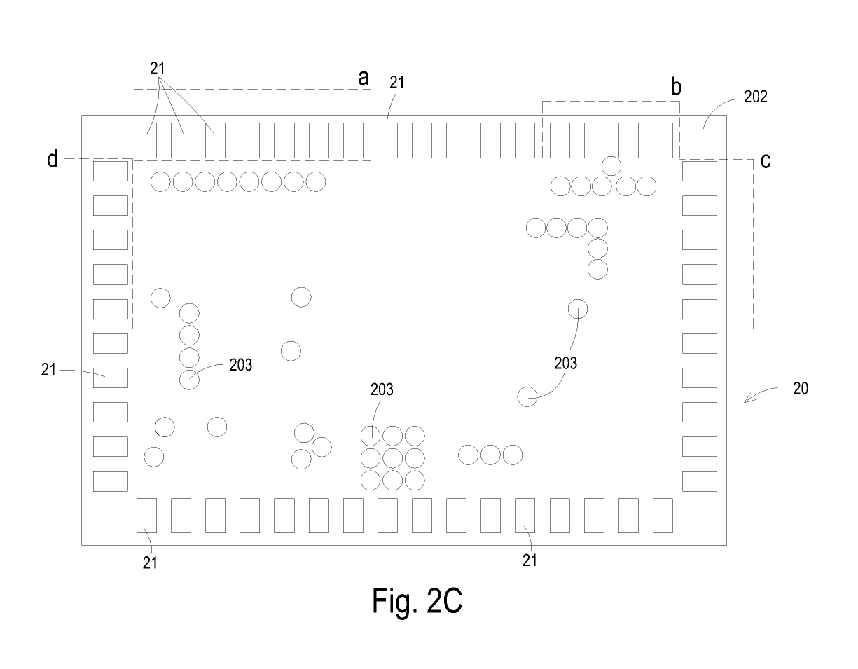

FIG. 2A is a schematic view of a package structure of a power module according to a first preferred embodiment of the present invention. FIG. 2B is a schematic top view of the package structure of the power module shown in FIG. 2A for illustrating the electronic components disposed on the top surface of the substrate. FIG. 2C is a schematic bottom view of the package structure of the power module shown in FIG. 2A for illustrating the layout configuration of multiple bond pads. Please refer to FIGS. 2A, 2B and 2C. An exemplary power module 2 is a power converter module such as a DC-to-DC converter module, an AC-to-DC converter module, and the like. The power module 2 is mounted on a motherboard (not shown) of an electronic device to convert the input voltage into a regulated voltage required for the electronic device. The power module 2 principally includes a substrate 20, a power converter and multiple bond pads 21. The substrate 20 is for example a printed circuit board having a top surface 201 and a bottom surface 202.

In this embodiment, the power converter includes a first semiconductor chip package 22, a second semiconductor chip package 23, a third semiconductor chip package 24, a fourth semiconductor chip package 25, and a plurality of discrete passive components (e.g., resistors R1˜R4, capacitors C1˜C11, and an inductor L1). The number of the semiconductor chip packages and the discrete passive components mounted on the substrate 20 may be varied according to the performance requirements of the power converter. The semiconductor chip packages 22˜25 are some power semiconductor chip packages for example power MOSFET and some IC chip package etc. The semiconductor chip packages 22˜25 and the passive components are electrically connected to each other through copper traces (not shown) so as to achieve the purpose of power conversion. The semiconductor chip packages 22˜25 and the passive components are mounted on the top surface 201 of the substrate 20. The semiconductor chip packages 22˜25 are formed by packaging respective chips according to well-known packaging technologies and are not redundantly described herein. It is noted that, however, those skilled in the art will readily observe that numerous modifications and alterations of the power converter may be made while retaining the teachings of the invention. The constituents, the number of constituents and the layout configuration of the power converter may be varied according to the performance requirements of the power module.

In this embodiment, the first semiconductor chip package 22 and the second semiconductor chip package 23 are implemented by power MOSFET packages. The first semiconductor chip package 22 is a high-side MOSFET package coupled to an external power source. The second semiconductor chip package 23 is a low-side MOSFET package connected to ground. The third semiconductor chip package 24 is a control integrated circuit that offers a driving signal to the gates electrodes of the first and the second semiconductor chip packages 22 and 23. In response to the driving signal, the first and the second semiconductor chip packages 22 and 23 are turned on or turned off. The fourth semiconductor chip package 25 supplies a constant voltage for the driver of the first semiconductor chip package 22.

Referring to FIGS. 2A and 2C again, multiple bond pads 21 are formed on the bottom surface 202 of the substrate 20. These bond pads 21 are exposed to the bottom surface 202 of the substrate 20 after the power module 2 is encapsulated with encapsulant 4 to prevent physical damage or corrosion. In accordance with a key feature of the present invention, the areas of the exposed bond pads 21 are substantially equal. It is preferred that at least some of the bond pads 21 are arranged on the peripheral region of the bottom surface 202 of the substrate 20. More preferably, at least some of the bond pads 21 are uniformly distributed over the peripheral region of the bottom surface 202 of the substrate 20. Moreover, at least some of the bond pads 21 are electrically connected to the semiconductor chip packages 22˜25 and the passive components on the top surface 201 of the substrate 20. As a consequence, after the power module 2 is mounted on the motherboard of the electronic device, the semiconductor chip packages 22˜25 and the passive components of the power module 2 are electrically connected to the conductive parts on the motherboard through the bond pads 21. Moreover, the heat generated from the power module 2 during operation can be conducted to the motherboard through at least some of the bond pads 21 for enhancing heat dissipation.

Besides the pads are electrically connected to the semiconductor chip packages or the passive components, several pure thermal pads which do not electrically connected with the semiconductor chip packages or the passive components are provided on the substrate 20 for increasing the heat-dissipating efficiency of the power module 2. And for thermally connected with the semiconductor chip packages or the passive components, thermal vias are provided in the substrate 20. Thus heat can be transmitted from the semiconductor chip packages or the passive components to the pure thermal pads through thermal vias. The locations and the number of the pure thermal pads or thermal vias 203 may be varied according to the amount of heat generated by the power module 2. For example, since the semiconductor chip packages 22˜25 are relatively high power components, more pure thermal pads or thermal vias 203 may be arranged on the locations perpendicularly corresponding to the semiconductor chip packages 22˜25 in order to enhance the heat-dissipating efficiency.

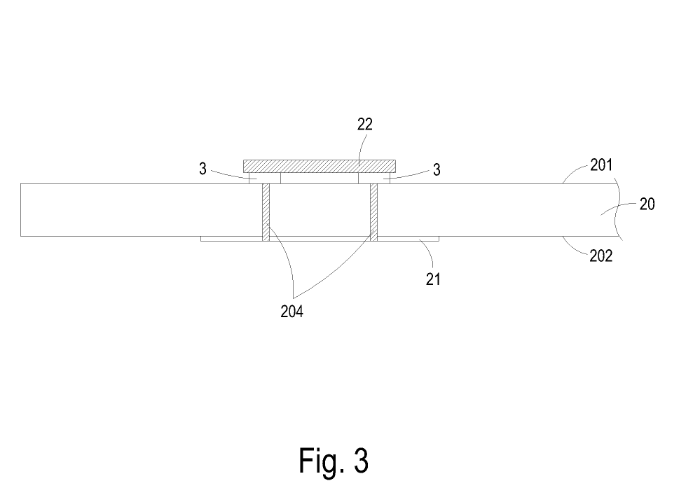

FIG. 3 is a schematic cross-sectional view illustrating arrangement of the semiconductor chip package 22, the substrate 20 and the bond pad 21. As shown in FIG. 3, the substrate 20 has a plurality of plated through holes 204 that communicate with the top surface 201 and the bottom surface 202 of the substrate 20. The plated through holes 204 proximate to the bottom surface 202 of the substrate 20 are connected with the bond pads 21. Optionally, thermally conductive material and/or electrically conductive material may be injected or filled into the plated through holes 204. Furthermore, the semiconductor chip package 22 is surface-mounted on the top surface 201 of the substrate 20 via solder paste 3 such that the conductive leads (not shown) of the semiconductor chip package 22 are connected to respective plated through holes 204. As a consequence, the semiconductor chip package 22 on the top surface 201 of the substrate 20 is electrically connected to the bond pads 21 and the heat generated from the semiconductor chip package 22 is conducted to the bond pads 21 through the plated through holes 204.

The I/O pin assignments that correlate with the bond pads 21 are also demonstrated with reference to FIG. 2C. For example, the bond pads 21 within the region “a” are assigned to the output voltage. The bond pads 21 within the region “b” are assigned to the input voltage. The bond pads 21 within the region “c” and “d” are assigned to the ground. The remaining bond pads 21 are assigned to for example the switch voltage, the constant voltage, the output voltage adjustment, and so on. It should be appreciated that it is within the spirit and scope of the present invention to modify the pin arrangements shown above.

In some embodiments, some of the bond pads 21 are used as thermal pads but not electrically connected to the power converter. For example, some of the bond pads 21 within the region “a” are assigned to the output voltage but the others are used as thermal pads.

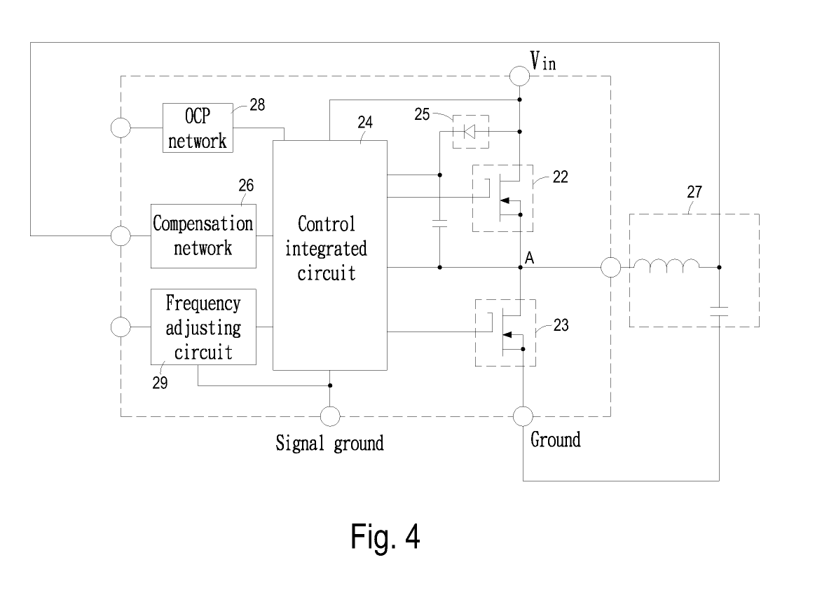

FIG. 4 is a schematic circuit diagram illustrating the power converter of the power module according to the present invention. The power converter of the power module 2 is for example a DC-to-DC converter, which includes a first semiconductor chip package 22, a second semiconductor chip package 23, a third semiconductor chip package 24, a fourth semiconductor chip package 25, a compensation network 26 and an output filter 27. The first semiconductor chip package 22 is a high-side MOSFET package and the second semiconductor chip package 23 is a low-side MOSFET package. The output filter 27 comprises an output inductor and an output capacitor. The drain electrode of the first semiconductor chip package 22 is coupled to the input voltage Vᵢₙ. The source electrode of the first semiconductor chip package 22 and the drain electrode of the second semiconductor chip package 23 are coupled together to define a phase node A. The source electrode of the second semiconductor chip package 23 is connected to ground. The output filter 27 is coupled to the phase node A for converting the rectangular waveform into a substantially DC output voltage. The control integrated circuit provided by the third semiconductor chip package 24 is electrically connected to the gate electrodes of the first and the second semiconductor chip packages 22, 23 and the compensation network 26. The third semiconductor chip package 24 further includes a pulse width modulation (PWM) circuit that controls the duty cycle of a square wave signal used to control the activation time of the first and the second semiconductor chip packages 22 and 23. One pin of the third semiconductor chip package 24 is connected to signal ground. Feedback signals reflecting the output voltage and/or current are provided to the third semiconductor chip package 24 via the compensation network 26 to determine the duty cycle of the PWM signal. The fourth semiconductor chip package 25 comprises a diode, which electrically connects to the input voltage Vᵢₙ and the third semiconductor chip package 24. The semiconductor chip package 25 supplies a constant voltage for the driver of the first semiconductor chip package 22. In some embodiment, the DC-to-DC converter of the power module 2 further includes an over current protection (OCP) network 28 and a frequency adjusting circuit 29. The frequency adjusting circuit 29 is composed of passive components for determining the clock frequency for the PWM circuit, as generally known in the art. The OCP network 28 and the frequency adjusting circuit 29 are electrically connected to the third semiconductor chip package 24 for providing over-current protection. It is noted that, however, those skilled in the art will readily observe that numerous modifications and alterations of the power converter may be made while retaining the teachings of the invention.

From the above description, since the power module is mounted on the motherboard via the bond pads with substantially identical areas according to a surface mount technology (SMT), the overall package size of the power module is reduced. Moreover, since the semiconductor chip packages mounted on the substrate are not easily damaged during the process of encapsulating the power module with the encapsulant, the product yield of the power module is enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power module comprising:
a substrate including a top surface and a bottom surface;
a power converter disposed on said substrate and including at lease one semiconductor chip package, said semiconductor chip package being disposed on said top surface of said substrate; and
a plurality of bond pads disposed on said bottom surface of said substrate, wherein at least some of said bond pads are electrically connected to said power converter and said plurality of bond pads have substantially identical area.

2. The power module according to claim 1 wherein at least some of said bond pads are arranged on a peripheral region of said bottom surface of said substrate.

3. The power module according to claim 2 wherein at least some of said bond pads are uniformly distributed over said peripheral region of said bottom surface of said substrate.

4. The power module according to claim 1 wherein at least some of said bond pads are contacted with said semiconductor chip package of said power converter such that the heat generated from said semiconductor chip package are conducted to said bond pads.

5. The power module according to claim 1 wherein a plurality of pure thermal pads are formed on said substrate corresponding to said semiconductor chip package such that the heat generated from said semiconductor chip package are conducted to said thermal pads.

6. The power module according to claim 5 wherein said pure thermal pads are formed on said substrate perpendicularly corresponding to said semiconductor chip package.

7. The power module according to claim 1 wherein a plurality of thermal vias formed in said substrate corresponding to said semiconductor chip package such that the heat generated from said semiconductor chip package are conducted to said thermal vias.

8. The power module according to claim 1 wherein said semiconductor chip package is a power chip package.

9. The power module according to claim 1 wherein said power converter further includes a plurality of passive components, which are electrically connected to said semiconductor chip package.

10. The power module according to claim 1 wherein said substrate is a printed circuit board.

11. The power module according to claim 1 wherein said power module is encapsulated with encapsulant.
